(19) United States
(12) Patent Application Publication
(10) Pub. No.: US 2003/0098506 A1
(43) Pub. Date: May 29, 2003

(54) Semiconductor device having a semiconductor chip and a lead substrate connected with each other through pads and patterned lead wires without short-circuiting the pads

(76) Inventors: Yoshiyuki Haraguchi, Tokyo (JP); Kiyoshi Adachi, Tokyo (JP)

Correspondence Address: Platon N. Mandros, BURNS, DOANE, SWECKER & MATHIS, L.L.P., P.O. Box 1404, Alexandria, VA, 22313-1404, US

(21) Appl. No.: 10/144,729

(22) Filed: May 15, 2002

(30) Foreign Application Priority Data
Nov. 27, 2001 (JP) 2001-361194

(51) Int. Cl. H01L 23/48; H01L 23/52; H01L 29/40

(52) U.S. Cl. 257/735

(57) ABSTRACT

A plurality of patterned lead wires equally spaced are arranged on both side ends of a lead substrate, a plurality of pads equally spaced are arranged on both side ends of a semiconductor chip, and the semiconductor chip is mounted on the lead substrate so as to connect the pads of each side end of the semiconductor chip with the patterned lead wires of the corresponding side end of the lead substrate. Widths of the patterned lead wires are smaller than a width of an open space between each pair of pads adjacent to each other in the semiconductor chip, and widths of the pads of the semiconductor chip are larger than a width of an open space between each pair of patterned lead wires adjacent to each other.

### BACKGROUND OF THE INVENTION

1. Field of the Invention

The present invention relates to a semiconductor device in which an electric connection mechanism not depending on a specification of the semiconductor chip is used.

2. Description of Related Art

FIG. 16 is a view showing a conventional semiconductor device. In FIG. 16, 11 indicates a semiconductor chip (hereinafter, simply called a chip), and 12 indicates a die pad on which the chip 11 is fixedly disposed. A plurality of pads 11a are arranged on both right and left side ends of the chip 11. In the example shown in FIG. 16, there are twelve pads 11a on the left side and seven pads 11a on the right side of the chip 11. In the semiconductor device, to connect the pads 11a to a lead frame (not shown) arranged in a peripheral area of the die pad 12, the chip 11 is fixed to the die pad 12, and the pads 11a are directly connected to the lead frame through a plurality of bonding wires 13 in a bonding operation.

FIG. 17 is a view showing another conventional semiconductor device. In FIG. 17, 11 indicates a chip, 14 indicates another chip, and 12 indicates a die pad on which the chips 11 and 14 are fixed disposed. In the same manner as in the conventional semiconductor device shown in FIG. 16, a plurality of pads 11a are arranged on both right and left side ends of the chip 11, and a plurality of pads 14a are arranged on both right and left side ends of the chip 14. To connect the chip 11 to the chip 14, each pad 11a facing the corresponding pad 14a is connected to the corresponding pad 14a through a bonding wire 15. Also, in the same manner as in the conventional semiconductor device shown in FIG. 16, the other pads 11a and 14a of the pads 11 and 14 are connected to a plurality of bonding wires 13 respectively.

Also, in cases where three chips or more are connected to each other in series, a plurality of bonding wires 13 are connected to all pads of the chips respectively in the same manner.

Because each of the conventional semiconductor devices has the above-described configuration, in cases where an electric connection line connecting a chip of the conventional semiconductor device and a lead frame connected to an external device is arranged to connect the conventional semiconductor device with the external device through the electric connection line, a plurality of lead terminals of the lead frame corresponding to a plurality of pads of the chip respectively are required, and the lead terminals of the lead frame are connected to the pads of the chip through a plurality of bonding wires in one-to-one correspondence. Also, in cases where a plurality of chips are prepared to be used for a semiconductor device, there is a case where sizes of the chips differ from each other, the number of pads in one chip differs from that in another chip even though the chips has the same size as each other, or a pitch of a plurality of pads of each chip differs from those of the other chips. In this case, a problem has arisen that it is required to form a lead frame for each chip. Also, there-is high probability that a lead frame arranged for a chip cannot be used for any other chips. In other words, a lead frame arranged for a chip cannot be widely used for any other chips, and it is required to form a lead frame for each type of chip. Therefore, the increase of the cost due to the formation of a lead frame for each chip cannot be avoided.

As is described above, in each conventional semiconductor device, it is required to prepare a lead frame for each chip used in the conventional semiconductor device. Because a plurality of lead frames are arranged for a plurality of chips prepared to be used for a semiconductor device and stock management for the lead frames is additionally required, it cannot be avoided that a manufacturing cost of the conventional semiconductor device having a semiconductor chip or more is increased. Also, in cases where the production of a specific type of chip is stopped, because a lead frame arranged for the specific type of chip cannot be used for another type of chip, a problem has arisen that it is required to abandon the lead frame arranged for the specific type of chip.

Therefore, in each conventional semiconductor device, in cases where a semiconductor chip or more are mounted on the conventional semiconductor device, the use of a lead frame for each chip is limited due to the difference in specification among the semiconductor chips. As a result, a problem has arisen that it cannot be avoided that a manufacturing cost of the conventional semiconductor device having a semiconductor chip or more is increased.

Also, as is described above, in cases where a plurality of pads arranged on a chip is connected to a plurality of lead terminals of a lead frame through a plurality of bonding wires in one-to-one correspondence by using a bonding device, a bonding pitch of the bonding wires connecting the pads and the lead terminals respectively is predetermined in a prescribed range in the bonding device. Therefore, in cases where a pad pitch of the chip is smaller than a minimum bonding pitch allowed for the bonding device, it is impossible to perform the wire bonding for the chip. As a result, the specification of each chip of the conventional semiconductor device is limited due to the specification of the bonding pitch predetermined in the bonding device, and it is required to arrange a plurality of pads arranged on each chip within the prescribed range of the bonding pitch predetermined in the bonding device. Therefore, a size of each chip of the conventional semiconductor device cannot be arbitrarily set.

### SUMMARY OF THE INVENTION

An object of the present invention is to provide, with due consideration to the drawbacks of the conventional semiconductor device, a semiconductor device in which a semiconductor chip or more are used regardless of specifications of the semiconductor chips or a specification of a bonding device and the increase of the cost in the manufacturing of the semiconductor device due to the specification predetermined for each semiconductor chip is suppressed.

The object is achieved by the provision of a semiconductor device including an electric connection pattern unit, which is arranged on a chip mounting surface of a supporting member and has a plurality of patterned lead wires equally spaced and making contact with a plurality of electric connection terminals equally spaced on a semiconductor chip on condition that an arrangement length of the group of patterned lead wires is equal to or longer than that of the group of electric connection terminals of the semiconductor chip, widths of the patterned lead wires are smaller than a width of an open space between each pair of electric connection terminals adjacent to each other in the semiconductor chip, and widths of the electric connection terminals of the semiconductor chip are larger than a width of an open space between each pair of patterned lead wires adjacent to each other.

In the above configuration, the widths of the patterned lead wires are smaller than the width of an open space between each pair of electric connection terminals adjacent to each other in the semiconductor chip, and the widths of the electric connection terminals of the semiconductor chip are larger than the width of an open space between each pair of patterned lead wires adjacent to each other. Therefore, when the semiconductor chip is merely mounted on the supporting member, each electric connection terminal of the semiconductor chip mounted on the supporting member can be always electrically connected to the corresponding patterned lead wire without electrically connecting each electric connection terminal of the semiconductor chip to the other electric connection terminals. Also, in cases where the arrangement length of the group of patterned lead wires is set to be equal to that of electric connection terminals of a chip having a maximum size and a maximum arrangement length among a plurality of chips prepared to be used for the semiconductor device, even though any semiconductor chip having a size smaller than the maximum-sized semiconductor chip is mounted on the supporting member, the supporting member with the patterned lead wires can be used for the semiconductor device. Also, even though a semiconductor chip of the maximum size having electric connection terminals, of which the number is smaller than that of the maximum-sized semiconductor chip, is mounted on the supporting member, the supporting member with the patterned lead wires can be used for the semiconductor device. Also, even though a semiconductor chip having a pitch of the electric connection terminals different from those of the other chips is mounted on the supporting member, the supporting member with the patterned lead wires can be used for the semiconductor device.

Accordingly, any chip can be used for the semiconductor device regardless of the specification of the chip, and the supporting member with the patterned lead wires can be widely used for various types of chips. As a result, a semiconductor device can be obtained on condition that the increase of the cost in the manufacturing of the semiconductor device due to the specification determined for each chip can be suppressed.

The object is also achieved by the provision of a semiconductor device including an electric connection pattern unit which corresponds to each pair of semiconductor chips adjacent to each other among a plurality of semiconductor chips, is arranged on a chip mounting surface of a supporting member and has a plurality of patterned lead wires equally spaced at another pitch and making contact with two groups of electric connection terminals of the pair of semiconductor chips to electrically connect the pair of semiconductor chips on condition that an arrangement length of the group of patterned lead wires is equal to or longer than those of the groups of electric connection terminals of the pair of semiconductor chips, widths of the patterned lead wires are smaller than a width of an open space between each pair of electric connection terminals adjacent to each other in each of the pair of semiconductor chips, and widths of the electric connection terminals of the pair of semiconductor chips are larger than a width of an open space between each pair of patterned lead wires adjacent to each other.

In the above configuration, when the semiconductor chips adjacent to each other are mounted on the supporting member, the electric connection terminals of one semiconductor chip can be always electrically connected to the electric connection terminals of the other semiconductor chip through the patterned lead wires placed on the supporting member in-one-to-one correspondence without electrically connecting each electric connection terminal of each semiconductor chip to the other electric connection terminals of the semiconductor chip. Accordingly, a plurality of semiconductor chips can be easily electrically connected to each other in series. Also, because no bonding wire is required to electrically connect each pair of semiconductor chips adjacent to each other, a process for the wire bonding in the manufacturing of the semiconductor device can be reduced.

The object is also achieved by the provision of a semiconductor device including an electric connection member which corresponds to each pair of semiconductor chips adjacent to each other among a plurality of semiconductor chips, has a plurality of patterned lead wires equally spaced at another pitch and is arranged between the pair of semiconductor chips so as to make contact with two groups of electric connection terminals of the pair of semiconductor chips and to electrically connect the pair of semiconductor chips on condition that an arrangement length of the group of patterned lead wires is equal to or longer than those of the groups of electric connection terminals of the pair of semiconductor chips, widths of the patterned lead wires are smaller than a width of an open space between each pair of electric connection terminals adjacent to each other in each of the pair of semiconductor chips, and widths of the electric connection terminals of the pair of semiconductor chips are larger than a width of an open space between each pair of patterned lead wires adjacent to each other.

In the above configuration, the widths of the patterned lead wires are smaller than the width of an open space between each pair of electric connection terminals adjacent to each other in each of the pair of semiconductor chips, and the widths of the electric connection terminals of the pair of semiconductor chips are larger than the width of an open space between each pair of patterned lead wires adjacent to each other. Therefore, when the electric connection member is merely arranged between each pair of semiconductor chips adjacent to each other, the electric connection terminals of one semiconductor chip can be always electrically connected to the electric connection terminals of the other semiconductor chip through the patterned lead wires of the electric connection member in-one-to-one correspondence without electrically connecting each electric connection terminal of each semiconductor chip to the other electric connection terminals of the semiconductor chip. Accordingly, a plurality of semiconductor chips can be easily electrically connected to each other in series. Also, because no bonding wire is required to electrically connect each pair of semiconductor chips adjacent to each other, a process for the wire bonding in the manufacturing of the semiconductor device can be reduced.

Also, in cases where the arrangement length of the group of patterned lead wires is set to be equal to that of electric connection terminals of a chip having a maximum size and a maximum arrangement length among a plurality of chips respectively prepared to be used for the semiconductor device, even though any semiconductor chip having a size smaller than the maximum-sized semiconductor chip is used, the electric connection through the patterned lead wires of the electric connection member can be reliably obtained. Also, even though a semiconductor chip of the maximum size having electric connection terminals, of which the number is smaller than that of the maximum-sized semiconductor chip, is used, the electric connection through the patterned lead wires of the electric connection member can be reliably obtained. Also, even though a semiconductor chip having a pitch of the electric connection terminals different from those of the other chips is used, the electric connection through the patterned lead wires of the electric connection member can be reliably obtained.

Accordingly, a semiconductor device can be obtained on condition that the increase of the cost in the manufacturing of the semiconductor device due to the specification determined for each chip can be suppressed.

### BRIEF DESCRIPTION OF THE DRAWINGS

FIG. 1 is a plan view showing a lead substrate used for a semiconductor device according to a first embodiment of the present invention;

FIG. 2A is a plan view of a semiconductor device in which the lead substrate shown in FIG. 1 is used;

FIG. 2B shows a positional relationship between a group of the patterned lead wires and a group of pads;

FIG. 3 is a plan view of another semiconductor device in which the lead substrate shown in FIG. 1 is used;

FIG. 4 is a plan view showing a lead substrate used for a semiconductor device according to a second embodiment of the present invention;

FIG. 5 is a plan view of a semiconductor device in which the lead substrate shown in FIG. 4 is used;

FIG. 6 is a plan view showing a lead substrate used for a semiconductor device according to a third embodiment of the present invention;

FIG. 7 is a plan view of a semiconductor device in which the lead substrate shown in FIG. 6 is used;

FIG. 8 is a plan view showing a lead substrate used for a semiconductor device according to a fourth embodiment of the present invention

FIG. 9 is a plan view of a semiconductor device in which the lead substrate shown in FIG. 8 is used;

FIG. 10 is a plan view showing a connection seal used for a semiconductor device according to a fifth embodiment of the present invention;

FIG. 11 is a plan view of a semiconductor device in which the connection seal shown in FIG. 10 is used;

FIG. 12 is a plan view showing a semiconductor device according to a sixth embodiment of the present invention;

FIG. 13 is a plan view showing another semiconductor device according to the sixth embodiment of the present invention;

FIG. 14 is a cross sectional view showing a semiconductor device according to a seventh embodiment of the present invention;

FIG. 15 is a plan view showing an inner plane of a socket used for the semiconductor device according to the seventh embodiment of the present invention;

FIG. 16 is a view showing a conventional semiconductor device; and

FIG. 17 is a view showing another conventional semiconductor device.

### DETAILED DESCRIPTION OF THE PREFERRED EMBODIMENTS

Embodiments of the present invention will now be described with reference to the accompanying drawings.

Embodiment 1

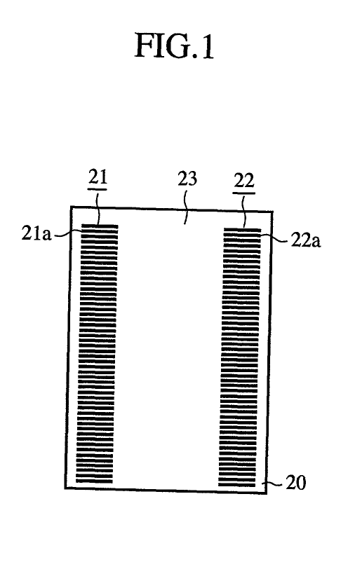

FIG. 1 is a plan view showing a lead substrate used for a semiconductor device according to a first embodiment of the present invention. In FIG. 1, 20 indicates a lead substrate (or a supporting member of a semiconductor chip). 21 and 22 indicate a pair of lead wire pattern units (or an electric connection pattern unit) respectively. The lead wire pattern unit 21 is arranged on the left side end of the lead substrate 20 in FIG. 1, the lead wire pattern unit 22 is arranged on the right side end of the lead substrate 20 in FIG. 1, and a chip mounting area (or a chip mounting surface) 23 is placed between the lead wire pattern units 21 and 22. A semiconductor chip described later is mounted on the chip mounting area 23.

The lead wire pattern unit 21 has a plurality of patterned lead wires 21a respectively extending from the chip mounting area 23 to a periphery (a left periphery in FIG. 1) of the lead substrate 20, and the lead wire pattern unit 22 has a plurality of patterned lead wires 22a respectively extending from the chip mounting area 23 to another periphery (a right periphery in FIG. 1) of the lead substrate 20. The patterned lead wires 21a are equally spaced at a first specified pitch, and the patterned lead wires 22a are equally spaced at the first specified pitch. Also, the patterned lead wires 21a are arranged in an arrangement direction at an arrangement length, and the patterned lead wires 22a are arranged in the arrangement direction at the arrangement length.

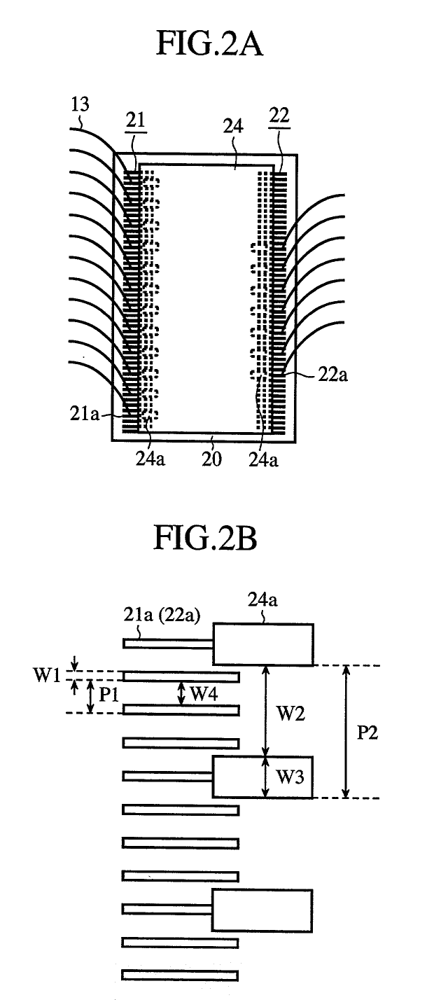

FIG. 2A is a plan view of a semiconductor device in which the lead substrate 20 shown in FIG. 1 is used. In FIG. 2A, 24 indicates a semiconductor chip (hereinafter, simply called a chip), and the chip 24 is mounted on the chip mounting area 23 of the lead substrate 20. The chip 24 has a plurality of pads (or a plurality of electric connection terminals) 24a placed on the right and left side ends in FIG. 2A. The pads 24a placed on the left side in FIG. 2A are equally spaced at a second specified pitch and are arranged in an arrangement direction at an arrangement length along the left side of the chip 24. Also, the pads 24a placed on the right side in FIG. 2A are equally spaced at the second specified pitch and are arranged in the arrangement direction at another arrangement length along the right side of the chip 24. The arrangement lengths of the group of patterned lead wires 21a and the group of patterned lead wires 22a are equal to or longer than the arrangement length of the pads 24a arranged on the right or left side ends of the chip 24. In the example of the semiconductor device shown in FIG. 2A, the arrangement lengths of the group of patterned lead wires 21a and the group of patterned lead wires 22a are equal to that of the pads 24a of the chip 24. The pads 24a of the chip 24 make contact with the patterned lead wires 21a and 22a of the lead wire pattern units 21 and 22 respectively. 13 indicates a bonding wire connected to one patterned lead wire 21a (or one patterned lead wire 22a) making contact with the corresponding pad 24a of the chip 24.

FIG. 2B shows a positional relationship between the group of the patterned lead wires 21a and 22a and the group of the pads 24a.

As shown in FIG. 2B, a width W1 of the patterned lead wires 21a and 22a is smaller than a width W2 of an open space formed between each pair of pads 24a adjacent to each other on the left side (or the right side) in FIG. 2A. Also, a width W3 of each pad 24a placed on the left side (or the right side) in FIG. 2A is larger than a width W4 of an open space formed between each pair of patterned lead wires 21a (or each patterned lead wire 22a) adjacent to each other. Therefore, the first specified pitch P1 (P1=W1+W4) of the patterned lead wires 21a or 22a is smaller than the second specified pitch P2 (P2=W2+W3) of the pads 24a of the chip 24.

As shown in FIG. 2A, when the chip 24 is arranged on the chip mounting area 23, the pads 24a of the chip 24 placed on the left side in FIG. 2A make contact with the patterned lead wires 21a, and the pads 24a of the chip 24 placed on the right side in FIG. 2A make contact with the patterned lead wires 22a. In this case, because the width W3 of each pad 24a is larger than the width W4 of an open space formed between each pair of patterned lead wires 21a (or each patterned lead wire 22a) adjacent to each other, each pad 24a placed on the left side in FIG. 2A necessarily makes contact with one patterned lead wire 21a, and each pad 24a placed on the right side in FIG. 2A necessarily makes contact with one patterned lead wire 22a. Also, because the width W1 of each patterned lead wire 21a is smaller than the width W2 of an open space formed between each pair of pads 24a adjacent to each other on the left side in FIG. 2A, each pad 24a placed on the left side in FIG. 2A is not electrically connected to the other pads 24a. Also, because the width W1 of each patterned lead wire 22a is smaller than the width W2 of an open space formed between each pair of pads 24a adjacent to each other on the right side in FIG. 2A, each pad 24a placed on the right side in FIG. 2A is not electrically connected to the other pads 24a.

Each patterned lead wire 21a or 22a making contact with the pad 24a is called a contact lead wire in this specification. A wire is connected to each contact lead wire 21a or 22a as one bonding wire 13. Therefore, a signal sent from an external device is received in the chip 24 of semiconductor device through one bonding wire 13, one contact lead wire 21a connected to the bonding wire 13 and one pad 24a making contact with the contact lead wire 21a, and another signal of the chip 24 of the semiconductor device is sent out to another external device through another pad 24a, one contact lead wire 22a making contact with the pad 24a and one bonding wire 13 connected to the contact lead wire 22a.

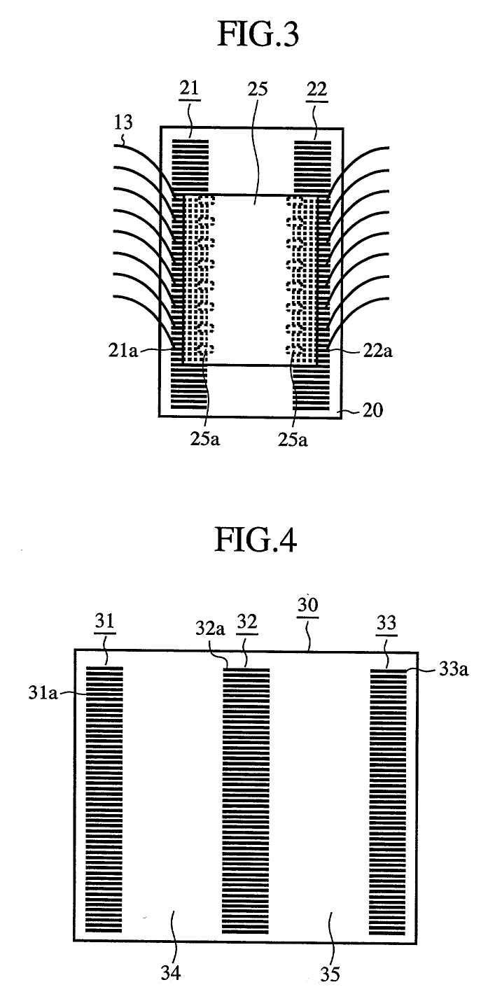

FIG. 3 is a plan view of another semiconductor device in which the lead substrate 20 shown in FIG. 1 is used. 25 indicates a chip mounted on the chip mounting area 23 of the lead substrate 20. The chip 25 has a plurality of pads 25a (or a plurality of electric connection terminals) placed at an arrangement length on the right and left side ends in FIG. 3. A size of the chip 25 is smaller than that of the chip 24, and the pads 25a of the chip 25 are equally spaced at the second specified pitch along both the right and left sides of the chip 25 in the same manner as in the chip 24.

As shown in FIG. 3, because the chip 25 is smaller than the chip 24, the arrangement lengths of the group of patterned lead wire 21a and the group of patterned lead wire 22a are longer than that of the group of pads 25a of the chip 25. Also, in the same manner as in the chip 24, the width of each pad 25a of the chip 25 is larger than the width of an open space formed between each pair of patterned lead wires 21a or 22a adjacent to each other, and the width of the patterned lead wires 21a and 22a is smaller than the width of an open space formed between each pair of pads 25a of the chip 25 adjacent to each other. Therefore, each pad 25a of the chip 25 necessarily makes contact with one patterned lead wire 21a or 22a, and each pad 25a of the chip 25 is not electrically connected to the other pads 25a. Therefore, in cases where a bonding wire 13 is connected to each contact lead wire 21a or 22a, the semiconductor device shown in FIG. 3 can be electrically connected to external devices.

Accordingly, in cases where the arrangement lengths of the groups of patterned lead wires 21a and 22a are respectively set to be equal to that of pads of a specific chip having a maximum size and a maximum arrangement length among a plurality of chips prepared to be used for a semiconductor device, a semiconductor device, in which a chip having an arbitrary size is mounted on the lead substrate 20, can be arbitrarily manufactured regardless of the size of the chip.

Also, in cases where a plurality of chips prepared to be used for a semiconductor device have pad pitches different from each other respectively, the pads of each chip are arranged on condition that a width of an open space between each pair of adjacent pads of the chip is larger than the width of the patterned lead wires 21a and 22a. In this case, even though the chips prepared to be used for a semiconductor device have different pad pitches, any chip can be used for a semiconductor device so as to make each pad of the chip be electrically connected to one patterned lead wire 21a or 22a without electrically connecting each pad of the chip to the other pads.

In the first embodiment, the pitch of the patterned lead wire 21a arranged on the left side of the lead substrate 20 is the same as that of the patterned lead wire 22a arranged on the right side of the lead substrate 20. However, it is applicable that a pitch of the patterned lead wire 21a arranged on the left side of the lead substrate 20 differs from that of the patterned lead wire 22a arranged on the right side of the lead substrate 20 on condition that a width of each pad is larger than both a width of an open space between each pair of patterned lead wires 21a adjacent to each other and a width of an open space between each pair of patterned lead wires 22a adjacent to each other.

Also, in the first embodiment, the pitch of the pads placed on the left side of the chip 24 or 25 is the same as that of the pads placed on the right side of the chip 24 or 25. However, it is applicable that a pitch of the pads placed on the left side of the chip 24 or 25 is the same as that of the pads placed on the right side of the chip 24 or 25 on condition that a width of the patterned lead wires 21a and 22a is smaller than both a width of an open space between each pair of pads adjacent to each other on the left side of the chip 24 or 25 and a width of an open space between each pair of pads adjacent to each other on the right side of the chip 24 or 25.

As is described above, in the first embodiment, the arrangement lengths of the group of patterned lead wires 21a and the group of patterned lead wires 22a on the lead substrate 20 are set to be equal to that of pads of a chip having a maximum size and a maximum arrangement length among a plurality of chips prepared to be used for a semiconductor device, the width of each pad of each chip is larger than the width of an open space between each pair of patterned lead wires 21a or 22a adjacent to each other, and the width of the patterned lead wires 21a and 22a is smaller than the width of an open space between each pair of pads of the chip adjacent to each other. Therefore, even though any chip having a size smaller than the maximum-sized chip is used for a semiconductor device or even though a chip of the maximum size having pads, of which the number is smaller than that of the maximum-sized chip, is used for a semiconductor device, the arrangement lengths of the group of patterned lead wires 21a and the group of patterned lead wires 22a on the lead substrate 20 are necessarily equal to or longer than that of the pads of the chip, and each pad of the chip used for a semiconductor device can be electrically connected to the patterned lead wire 21a or 22a without electrically connecting each pad of the chip to the other pads. Accordingly, any chip can be used for the semiconductor device having the lead substrate 20 regardless of the specification of the size of the chip, and the lead substrate 20 with the patterned lead wires 21a and 22a functioning as a plurality of lead terminals of a lead frame can be widely used for various types of chips. As a result, the increase of the cost in the manufacturing of the semiconductor device due to the specification of the size determined for each chip can be suppressed.

Also, in the first embodiment, even though the chips prepared to be used for a semiconductor device have pad pitches different from each other, because the pads of each chip are arranged on condition that the width of an open space between each pair of adjacent pads of the chip is larger than the width of the patterned lead wires 21a and 22a, any chip can be used for a semiconductor device so as to make each pad of the chip be electrically connected to one patterned lead wire 21a or 22a without electrically connecting each pad of the chip to the other pads.

Accordingly, any chip can be used for the semiconductor device regardless of the specification of the pad pitch of the chip, and the lead substrate 20 with the patterned lead wires 21a and 22a can be widely used for various types of chips. As a result, the increase of the cost in the manufacturing of the semiconductor device due to the specification of the pad pitch determined for each chip can be suppressed.

Embodiment 2

FIG. 4 is a plan view showing a lead substrate used for a semiconductor device according to a second embodiment of the present invention. In FIG. 4, 30 indicates a lead substrate (or a supporting member of a semiconductor chip). 31 and 33 indicate two lead wire pattern units (or two external electric connection pattern units) arranged on the lead substrate 30 respectively. 32 indicate a lead wire pattern unit (or an electric connection pattern unit) arranged on the lead substrate 30 respectively. The lead wire pattern unit 31 is arranged on the left side end of the lead substrate 30 in FIG. 4, the lead wire pattern unit 33 is arranged on the right side end of the lead substrate 30 in FIG. 4, and the lead wire pattern unit 32 is arranged in the center of the lead substrate 30 in FIG. 4. Also, a chip mounting area (or a chip mounting surface) 34 is placed between the lead wire pattern units 31 and 32 on the lead substrate 30, and a chip mounting area (or a chip mounting surface) 35 is placed between the lead wire pattern units 32 and 33 on the lead substrate 30. A chip described later is mounted on each of the chip mounting areas 34 and 35.

The lead wire pattern unit 31 has a plurality of patterned lead wires (or a plurality of external patterned lead wires) 31a respectively extending from the chip mounting area 34 to the periphery of the lead substrate 30, the lead wire pattern unit 32 has a plurality of patterned lead wires 32a respectively extending from the chip mounting area 34 to the chip mounting area 35, and the lead wire pattern unit 33 has a plurality of patterned lead wires (or a plurality of external patterned lead wires) 33a respectively extending from the chip mounting area 35 to the periphery of the lead substrate 30. The patterned lead wires 31a are equally spaced at a first specified pitch, the patterned leadwires 32a are equally spaced at the first specified pitch, and the patterned lead wires 33a are equally spaced at the first specified pitch. Also, the patterned lead wires 31a are arranged in an arrangement direction at an arrangement length, the patterned lead wires 32a are arranged in the arrangement direction at the arrangement length, and the patterned lead wires 33a are arranged in the arrangement direction at the arrangement length.

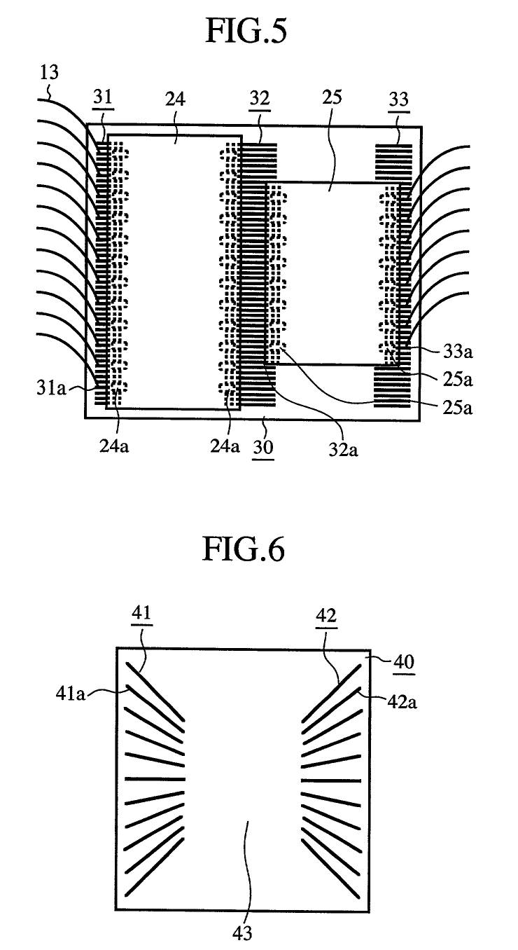

FIG. 5 is a plan view of a semiconductor device in which the lead substrate 30 shown in FIG. 4 is used. In FIG. 5, the chip 24 is mounted on the chip mounting area 34 of the lead substrate 30, and the chip 25 is mounted on the chip mounting area 35 of the lead substrate 30. The arrangement lengths of the group of patterned lead wires 31a, the group of patterned lead wires 32a and the group of patterned lead wires 33a are equal to or longer than the arrangement length of the group of pads 24a of the chip 24 and the arrangement length of the group of pads 25a of the chip 25. In the example of the semiconductor device shown in FIG. 5, the arrangement lengths of the group of patterned lead wires 31a, the group of patterned lead wires 32a and the group of patterned lead wires 33a are equal to that of the group of pads 24a of the chip 24.

Also, a width of the patterned lead wires 31a, 32a and 33a is smaller than the width of an open space formed between each pair of pads adjacent to each other in the chips 24 and 25, and the width of each pad in the chips 24 and 25 is larger than a width of an open space formed between each pair of patterned lead wires 31a, 32a or 33a adjacent to each other. Therefore, the first specified pitch in the patterned lead wires 31a, 32a or 33a is smaller than the second specified pitch of the pads of the chips 24 and 25.

As shown in FIG. 5, when the chip 24 is arranged on the chip mounting area 34, the pads 24a placed on the left side of the chip 24 make contact with the patterned lead wires 31a, and the pads 24a placed on the right side of the chip 24 make contact with the patterned lead wires 32a. In this case, because the width of each pad 24a of the chip 24 is larger than the width of an open space between each pair of patterned lead wires 31a or 32a adjacent to each other, each pad 24a of the chip 24 placed on the left side necessarily makes contact with one patterned lead wire 31a, and each pad 24a of the chip 24 placed on the right side necessarily makes contact with one patterned lead wire 32a. Also, because the width of the patterned lead wires 31a and 32a is smaller than the width W2 of an open space formed between each pair of pads 24a of the chip 24 adjacent to each other, each pad 24a of the chip 24 is not electrically connected to the other pads 24a of the chip 24.

Also, when the chip 25 is arranged on the chip mounting area 35, the pads 25a placed on the left side of the chip 25 make contact with the patterned lead wires 32a, and the pads 25a placed on the right side of the chip 25 make contact with the patterned lead wires 33a. In this case, because the width of the pads 25a of the chip 25 is larger than the width of an open space between each pair of patterned lead wires 32a or 33a adjacent to each other, each pad 25a placed on the left side of the chip 25 necessarily makes contact with one patterned lead wire 32a, and each pad 25a placed on the right side of the chip 25 necessarily makes contact with one patterned lead wire 33a. Also, because the width of the patterned lead wires 32a and 33a is smaller than the width of an open space between each pair of pads 25a of the chip 25 adjacent to each other, each pad 25a of the chip 25 is not electrically connected to the other pads 25a of the chip 25.

In this case, the chips 24 and 25 are arranged on the lead substrate 30 on condition that the patterned lead wires 32a connected to the pads 24a of the chip 24 are the same as those connected to the pads 25a of the chip 25 and each pad 24a of the chip 24 is connected to one pad 25a of the chip 25 corresponding to the pad 24 in signal transmission through one patterned lead wire 32a.

Each patterned lead wire 31a, 32a or 33a making contact with the pad is called a contact lead wire in this specification. A bonding wire 13 is connected to each contact lead wire 31a or 33a but is not connected to any contact lead wire 32a. Therefore, a signal sent from an external device is received in the chip 24 of the semiconductor device through one bonding wire 13, one contact lead wire 31a connected to the bonding wire 13 and one pad making contact with the contact lead wire 31a, and another signal of the chip 24 of the semiconductor device is sent out to the chip 25 through another pad 24a of the chip 24, one contact lead wire 32a making contact with the pad 24a and the pad 25a of the chip 25 making contact with the contact lead wire 32a. Thereafter, a signal of the chip 25 is sent out to another external device through one pad 25a of the chip 25, one contact lead wire 33a making contact with the pad 25a and one bonding wire 13 connected to the contact lead wire 33a.

Accordingly, in cases where the arrangement lengths of the groups of patterned lead wires 31a, 32a and 33a are respectively set to be equal to that of pads of a specific chip having a maximum size and a maximum arrangement length among a plurality of chips prepared to be used for a semiconductor device, a semiconductor device, in which a pair of chips having arbitrary sizes respectively are used for a semiconductor device, can be arbitrarily manufactured regardless of the sizes of the chips.

In the second embodiment, the two chips 24 and 25 are mounted on the lead substrate 30 to obtain a semiconductor device. However, it is applicable that three chips or more be mounted on three chip mounting areas or more of a lead substrate. In this case, a plurality of lead wire pattern units 32 are arranged in the center of the lead substrate at prescribed intervals.

Also, in cases where a plurality of chips prepared to be used for a semiconductor device have pad pitches different from each other respectively, the pads of each chip are arranged on condition that a width of an open space between each pair of adjacent pads of the chip is larger than the width of the patterned lead wires 31a, 32a and 33a. In this case, even though the chips prepared to be used for a semiconductor device have different pad pitches, any pair of chips can be used for a semiconductor device so as to make each pad of the chips be electrically connected to one patterned lead wire 31a, 32a or 33a without electrically connecting each pad of the chips to the other pads.

As is described above, in the second embodiment, the arrangement lengths of the group of patterned lead wires 31a, the group of patterned lead wires 32a and the group of patterned lead wires 33a on the lead substrate 30 are set to be equal to that of pads of a chip having a maximum size and a maximum arrangement length among a plurality of chips prepared to be used for a semiconductor device, the width of each pad of each chip is larger than the width of an open space between each pair of patterned lead wires 31a, 32a or 33a adjacent to each other, and the width of the patterned lead wires 31a, 32a and 33a is smaller than the width of an open space between each pair of pads adjacent to each other. Therefore, even though any chips having sizes smaller than the maximum-sized chip are used for a semiconductor device or even though chips of the maximum size respectively having pads, of which the number is smaller than that of the maximum-sized chip, are used for a semiconductor device, the arrangement lengths of the group of patterned lead wires 31a, the group of patterned lead wires 32a and the group of patterned lead wires 33a on the lead substrate 30 are necessarily equal to or longer than that of the pads of each chip, and each pad of the chips used for a semiconductor device can be electrically connected to the patterned lead wire 31a, 32a or 33a without electrically connecting each pad of the chips to the other pads. Accordingly, any chips can be used for a semiconductor device regardless of the specifications of the chip size of the chips, and the lead substrate 30 with the patterned lead wires 31a, 32a and 33a functioning as a plurality of lead terminals of a lead frame can be widely used for various types of chips. As a result, the increase of the cost in the manufacturing of the semiconductor device due to the specification of the chip size determined for each chip can be suppressed.

Also, in the second embodiment, even though a plurality of chips prepared to be used for a semiconductor device have pad pitches different from each other, because the pads of each chip are arranged on condition that the width of an open space between each pair of adjacent pads of the chip is larger than the width of the patterned lead wires 31a, 32a and 33a, any chip can be used for a semiconductor device so as to make each pad of the chip be electrically connected to one patterned lead wire 31a, 32a or 33a without electrically connecting each pad of the chip to the other pads. Accordingly, any chips can be used for a semiconductor device regardless of the specification of the pad pitch of the chip, and the lead substrate 30 with the patterned lead wires 31a, 32a and 33a can be widely used for various types of chips. As a result, the increase of the cost in the manufacturing of the semiconductor device due to the specification of the pad pitch determined for each chip can be suppressed.

Also, in the second embodiment, when a plurality of chips are merely mounted on a plurality of chip mounting areas of a lead substrate, pads of one chip are electrically connected to pads of another pad through the patterned lead wires 32a in one-to-one correspondence without using any bonding wires. Therefore, in cases where a plurality of chips are electrically connected to each other in a semiconductor device, it is not required to connect pads of each chip with pads of another chip through bonding wires Accordingly, a process for connecting pads of each chip with pads of another chip through bonding wires can be reduced in the manufacturing of a semiconductor device, and the cost in the manufacturing of the semiconductor device due to the connection of bonding wires can be reduced.

### Embodiment 3

FIG. 6 is a plan view showing a lead substrate used for a semiconductor device according to a third embodiment of the present invention. In FIG. 6, 40 indicates a lead substrate (or a supporting member), and 41 and 42 indicate two lead wire pattern units (or a plurality of electric connection pattern units) arranged on the lead substrate 40 respectively. The lead wire pattern unit 41 is arranged on the left side end of the lead substrate 40 in FIG. 6, and the lead wire pattern unit 42 is arranged on the right side end of the lead substrate 40 in FIG. 6. Also, a chip mounting area (or a chip mounting surface) 43 is placed between the lead wire pattern units 41 and 42 on the lead substrate 40.

The lead wire pattern unit 41 has a plurality of patterned lead wires 41a, and the lead wire pattern unit 42 has a plurality of patterned lead wires 42a. A plurality of inner portions of the patterned lead wires 41a facing the chip mounting area 43 are spaced at an inner pitch which is smaller than a pitch of pads of a chip described later, and an arrangement length of the inner portions of the patterned lead wires 41a facing the chip mounting area 43 is equal to that of the pads of the chip. Also, a plurality of outer portions of the patterned lead wires 41a facing the outer circumference of the lead substrate 40 are spaced at an outer pitch which is larger than the inner pitch of the inner portions of the patterned lead wires 41a. Therefore, the pitch of the patterned lead wires 41a is gradually increased from the inner pitch to the outer pitch in a direction from the chip mounting area 43 to the outer circumference of the lead substrate 40. In the same manner, a plurality of inner portions of the patterned lead wires 42a facing the chip mounting area 43 are spaced at the inner pitch, a plurality of outer portions of the patterned lead wires 42a facing the outer circumference of the lead substrate 40 are spaced at the outer pitch, and an arrangement length of the inner portions of the patterned lead wires 42a facing the chip mounting area 43 is equal to that of the pads of the chip.

The outer pitch of the patterned lead wires 41a and 42a is set to be equal to a bonding pitch of a plurality of bonding wires 13 predetermined in a bonding device (not show).

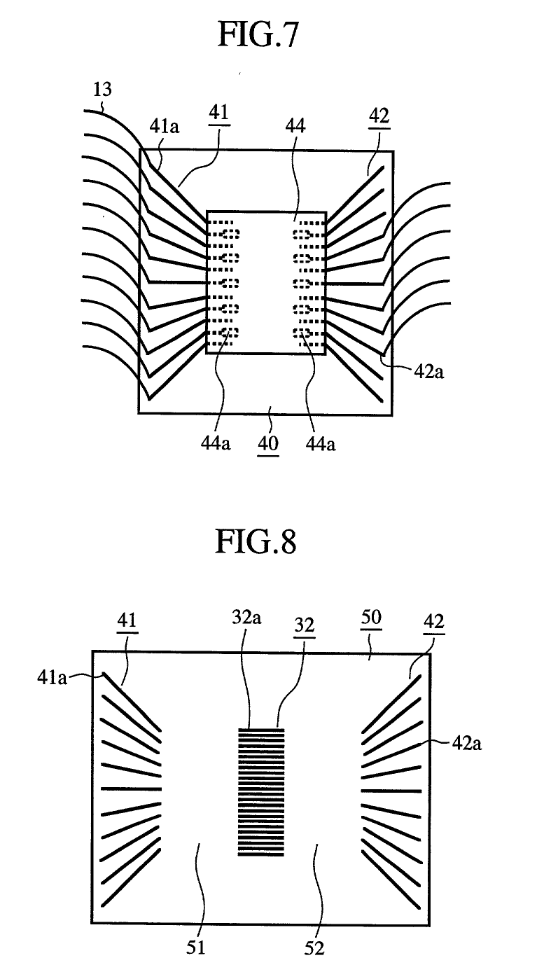

FIG. 7 is a plan view of a semiconductor device in which the lead substrate 40 shown in FIG. 6 is used. In FIG. 7, a chip 44 is mounted on the chip mounting area 43 of the lead substrate 40. A plurality of pads (or a plurality of electric connection terminals) 44a are arranged on the right and left side ends (in FIG. 7) of the chip 44. The pads 44a arranged on the left side are equally spaced at a pitch larger than the inner pitch of the patterned lead wires 41a, and the pads 44a arranged on the right side are equally spaced at a pitch larger than the inner pitch of the patterned lead wires 41a.

A width of each pad 44a of the chip 44 is larger than a width of an open space between the inner portions of each pair of patterned lead wires 41a or 42a adjacent to each other, and a width of each patterned lead wire 41a or 42a is smaller than a width of an open space between each pair of pads 44a of the chip 44 adjacent to each other. The arrangement lengths of the group of patterned lead wires 41a and the group of patterned lead wires 42a are equal to the arrangement length of the pads 44a of the chip 44.

As shown in FIG. 7, when the chip 44 is arranged on the chip mounting area 43, the pads 44a arranged on the left side end of the chip 44 make contact with the inner portions of the patterned lead wires 41a, and the pads 44a arranged on the right side end of the chip 44 make contact with the inner portions of the patterned lead wires 42a. In this case, because the width of each pad 44a of the chip 44 is larger than the width of an open space formed between the inner portions of each pair of patterned lead wires 41a or 42a adjacent to each other, each pad 44a arranged on the left side end of the chip 44 necessarily makes contact with the inner portion of one patterned lead wire 41a, and each pad 44a arranged on the right side end of the chip 44 necessarily makes contact with the inner portion of one patterned lead wire 42a. Also, because the width of each patterned lead wire 41a is smaller than the width of an open space formed between each pair of pads 44a adjacent to each other on the left side of the chip 44, each pad 44a arranged on the left side of the chip 44 is not electrically connected to the other pads 44a. Also, because the width of each patterned lead wire 42a is smaller than the width of an open space formed between each pair of pads 44a adjacent to each other on the right side of the chip 44, each pad 44a arranged on the right side of the chip 44 is not electrically connected to the other pads 44a.

Each patterned lead wire 41a or 42a making contact with one pad 44a of the chip 44 is called a contact lead wire in this specification. A bonding wire 13 is connected to the outer portion of each contact lead wire 41a or 42a by using the bonding device. Therefore, a signal sent from an external device is received in the chip 24 of semiconductor device through one bonding wire 13, one contact lead wire 41a connected to the bonding wire 13 and one pad 44a making contact with the contact lead wire 41a, and another signal of the chip 44 of the semiconductor device is sent out to another external device through another pad 44a, one contact lead wire 42a making contact with the pad 44a and one bonding wire 13 connected to the contact lead wire 42a.

As is described above, in the third embodiment, the width of each pad 44a of the chip 44 is larger than the width of an open space between the inner portions of each pair of patterned lead wires 41a or 42a adjacent to each other, the width of each patterned lead wire 41a or 42a is smaller than the width of an open space between each pair of pads 44a of the chip 44 adjacent to each other, and the pads 44a of the chip 44 make contact with only the inner portions of the patterned lead wires 41a and 42a. Therefore, even though a bonding pitch of the bonding device is larger than a pitch of the pads 44a of the chip 44, each pad 44a of the chip 44 can reliably make contact with the inner portion of the corresponding patterned lead wire 41a or 42a without being electrically connected with the other pads 44a, and arrangement lengths of both the inner portions of the patterned lead wires 41a and the inner portions of the patterned lead wires 42a can be shortened. Therefore, an area required to arrange a plurality of electric connection paths (or the patterned lead wires 41a and 42a) for the pads 44a of the chip 44 can be reduced. In particular, in cases where the arrangement lengths of the group of patterned lead wires 41a and the group of patterned lead wires 42a are set to be equal to that of the pads 44a of the chip 44, the area required to form the electric connection path for the pads 44a of the chip 44 can be further reduced. Accordingly, a small-sized semiconductor device can be obtained.

Also, in the third embodiment, even though the pitch of the pads 44a of the chip 44 is smaller than a minimum bonding pitch of the bonding wires 13 predetermined in the bonding device, the outer pitch of the patterned lead wires 41a and 42a facing the outer circumference of the lead substrate 40 can be set to be equal to a bonding pitch of the bonding wires 13 predetermined in the bonding device, and the bonding wires 13 connecting the pads 44a of the chip 44 and the patterned lead wires 41a and 42a respectively can be reliably arranged in the semiconductor device. Accordingly, the chip 44 can be used for the semiconductor device with the lead substrate 40 regardless of a specification of the bonding pitch predetermined in the bonding device, a size of the chip 44 can be arbitrarily set, and a small-sized chip can be used for the semiconductor device.

Also, in the third embodiment, even though any chip having a size smaller than the maximum-sized chip is used for a semiconductor device or even though a chip of the maximum size having pads, of which the number is smaller than that of the maximum-sized chip, is used for a semiconductor device, each pad of the chip can be electrically connected to the patterned lead wire 41a or 42a without electrically connecting each pad of the chip to the other pads, in the same manner as in the first embodiment. Accordingly, any chip can be used for a semiconductor device regardless of the specification of the size of the chip, the lead substrate 40 with the patterned lead wires 41a and 42a functioning as a plurality of lead terminals of a lead frame can be widely used for various types of chips, and the increase of the cost in the manufacturing of the semiconductor device due to the specification of the size determined for the chip can be suppressed.

Embodiment 4

FIG. 8 is a plan view showing a lead substrate used for a semiconductor device according to a fourth embodiment of the present invention. The constituent elements, which are the same as those shown in FIG. 4 and FIG. 6, are indicated by the same reference numerals as those of the constituent elements shown in FIG. 4 and FIG. 6, and additional description of those constituent elements is omitted.

In FIG. 8, 50 indicates a lead substrate (or a supporting member). The patterned lead wires 41a of the lead wire pattern unit 41 are arranged on the left side end of the lead substrate 50, the patterned lead wires 42a of the lead wire pattern unit 42 is arranged on the right side end of the lead substrate 50, and the patterned lead wires 32a of the lead wire pattern unit 32 is arranged in the center of the lead substrate 50. Also, a chip mounting area (or a chip mounting surface) 51 is placed between the lead wire pattern units 41 and 32 on the lead substrate 50, and a chip mounting area (or a chip mounting surface) 52 is placed between the lead wire pattern units 32 and 42 on the lead substrate 50.

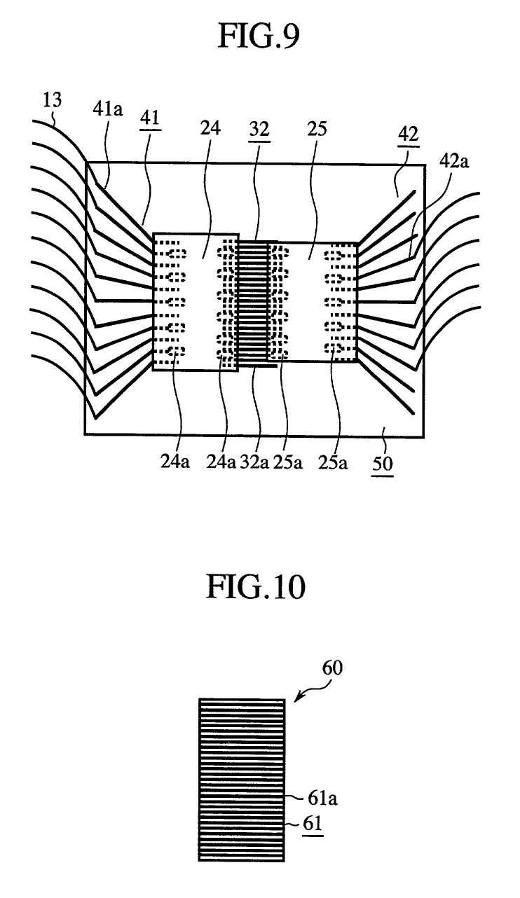

FIG. 9 is a plan view of a semiconductor device in which the lead substrate 50 shown in FIG. 8 is used. In FIG. 9, the chip 24 is mounted on the chip mounting area 51 of the lead substrate 50, and the chip 25 is mounted on the chip mounting area 52 of the lead substrate 50.

When the chip 24 is arranged on the chip mounting area 51, the pads 24a arranged on the left side end of the chip 24 make contact with the patterned lead wires 41a, and the pads 24a arranged on the right side end of the chip 24 make contact with the patterned lead wires 32a. In this case, because the width of each pad 24a of the chip 24 is larger than both the width of an open space between the inner portions of each pair of adjacent patterned lead wires 41a and the width of an open space between each pair of adjacent patterned lead wires 32a, each pad 24a of the chip 24 arranged on the left side end of the chip 24 necessarily makes contact with the inner portion of one patterned lead wire 41a, and each pad 24a of the chip 24 arranged on the right side end of the chip 24 necessarily makes contact with one patterned lead wire 32a. Also, because the width of each patterned lead wire 41a or 32a is smaller than the width of an open space formed between each pair of pads 24a adjacent to each other on the chip 24, each pad 24a of the chip 24 is not electrically connected to the other pads 24a.

Also, when the chip 25 is arranged on the chip mounting area 52, because the width of each pad 25a of the chip 25 is larger than both the width of an open space between each pair of adjacent patterned lead wires 32a and the width of an open space between the inner portions of each pair of adjacent patterned lead wires 42a, each pad 25a of the chip 25 arranged on the left side end of the chip 25 necessarily makes contact with one patterned lead wire 32a, and each pad 25a of the chip 25 arranged on the right side end of the chip 25 necessarily makes contact with the inner portion of one patterned lead wire 42a. Also, because the width of each patterned lead wire 32a or 42a is smaller than the width of an open space formed between each pair of pads 25a adjacent to each other on the chip 25, each pad 25a of the chip 25 is not electrically connected to the other pads 25a.

Each patterned lead wire 41a, 32a or 42a making contact with one pad is called a contact lead wire in this specification. A bonding wire 13 is connected to each contact lead wire 41a or 42a. Therefore, a signal sent from an external device is received in the chip 24 of the semiconductor device through one bonding wire 13, one contact lead wire 41a connected to the bonding wire 13 and one pad 24a making contact with the contact lead wire 41a, and another signal of the chip 24 of the semiconductor device is sent out to the chip 25 through another pad 24a of the chip 24, one contact lead wire 32a making contact with the pad 24a and the pad 25a of the chip 25 making contact with the contact lead wire 32a. Thereafter, a signal of the chip 25 is sent out to another external device through one pad 25a of the chip 25, one contact lead wire 42a making contact with the pad 25a and one bonding wire 13 connected to the contact lead wire 42a.

In the fourth embodiment, the two chips 24 and 25 are used for a semiconductor device to obtain the semiconductor device. However, it is applicable that three chips or more be mounted on three chip mounting areas or more of a lead substrate. In this case, the lead wire pattern units 41 and 42 are arranged on both side ends of the lead substrate, and a plurality of lead wire pattern units 32 are arranged in the center of the lead substrate at prescribed intervals.

As is described above, in the fourth embodiment, the contact lead wires 32a of the lead wire pattern unit 32 are arranged on the lead substrate 50 in the semiconductor device in addition to the configuration of the contact lead wires 41a and 42a of the lead wire pattern units 41 and 42 of the third embodiment, the arrangement length of the patterned lead wires 32a is set to be equal to that of pads of a chip having a maximum size and a maximum arrangement length among a plurality of chips prepared to be used for the semiconductor device, the width of each pad of any chip used for a semiconductor device is larger than the width of an open space between each pair of patterned lead wires 32a adjacent to each other, and the width of the patterned lead wires 32a is smaller than the width of an open space between each pair of adjacent pads of the chip. Therefore, even though any chips having sizes smaller than the maximum-sized chip are used for a semiconductor device or even though chips of the maximum size respectively having pads, of which the number is smaller than that of the maximum-sized chip, are used for a semiconductor device, the arrangement length of the patterned lead wires 32a is necessarily equal to or longer than that of the pads of each chip, and each pad of the chips used for a semiconductor device can be electrically connected to the patterned lead wire 41a, 32a or 42a without electrically connecting each pad of the chips to the other pads. Accordingly, any chip can be used for a semiconductor device regardless of the specification of the size of the chip, and the lead substrate 50 with the patterned lead wires 41a, 32a and 42a functioning as a plurality of lead terminals of a lead frame can be widely used for various types of chips. As a result, the increase of the cost in the manufacturing of the semiconductor device due to the specification of the size determined for each chip can be suppressed.

Also, in the fourth embodiment, even though a plurality of chips prepared to be used for a semiconductor device have pad pitches different from each other, because a width of an open space between each pair of adjacent pads of the chip is larger than the width of the patterned lead wires 41a, 32a and 42a, each chip can be used for a semiconductor device so as to make each pad of the chip be electrically connected to one patterned lead wire 41a, 32a and 42a without electrically connecting each pad of the chip to the other pads. Accordingly, any chip can be used for a semiconductor device regardless of the specification of the pad pitch of the chip, and the lead substrate 50 with the patterned lead wires 41a, 32a and 42a can be widely used for various types of chips. As a result, the increase of the cost in the manufacturing of the semiconductor device due to the specification of the pad pitch determined for each chip can be suppressed.

Also, in the fourth embodiment, when a plurality of chips are mounted on a plurality of chip mounting areas of a lead substrate, the chips are electrically connected to each other through the patterned lead wires 32a without using any bonding wires. Therefore, in cases where a plurality of chips are electrically connected to each other in a semiconductor device, it is not required to connect pads of each chip with pads of another chip through bonding wires respectively. Accordingly, a process for connecting pads of each chip with pads of another chip through bonding wires can be reduced in the manufacturing of a semiconductor device, and the cost in the manufacturing of the semiconductor device due to the connection of bonding wires can be reduced.

Also, in the forth embodiment, even though the pitch of pads of a pair of chips arranged on both side ends of the lead substrate 50 is smaller than a minimum bonding pitch of the bonding wires 13 predetermined in the bonding device, the outer pitch of the patterned lead wires 41a and 42a facing the outer circumference of the lead substrate 50 can be set to be equal to a bonding pitch of the bonding wires 13 predetermined in the bonding device, and the bonding wires 13 connecting the pads of the chips and the patterned lead wires 41a and 42a respectively can be reliably arranged in the semiconductor device. Accordingly, the chips can be used for the semiconductor device with the lead substrate 50 regardless of a specification of the bonding pitch predetermined in the bonding device, sizes of the chips can be arbitrarily set, and small-sized chips can be used for the semiconductor device.

Embodiment 5

FIG. 10 is a plan view showing a connection seal used for a semiconductor device according to a fifth embodiment of the present invention. In FIG. 10, 60 indicates a connection seal (or an electric connection member of a semiconductor chip), and a lead wire pattern unit 61 is arranged on a main surface of the connection seal 60. The lead wire pattern unit 61 has a plurality of patterned lead wires 61a at an arrangement length. The patterned lead wires 61a is equally spaced at a pitch, and the arrangement length of the patterned lead wires 61a of the connection seal 60 is set to be equal to that of pads of a specific chip having a maximum size and a maximum arrangement length among a plurality of chips prepared to be used in the semiconductor device.

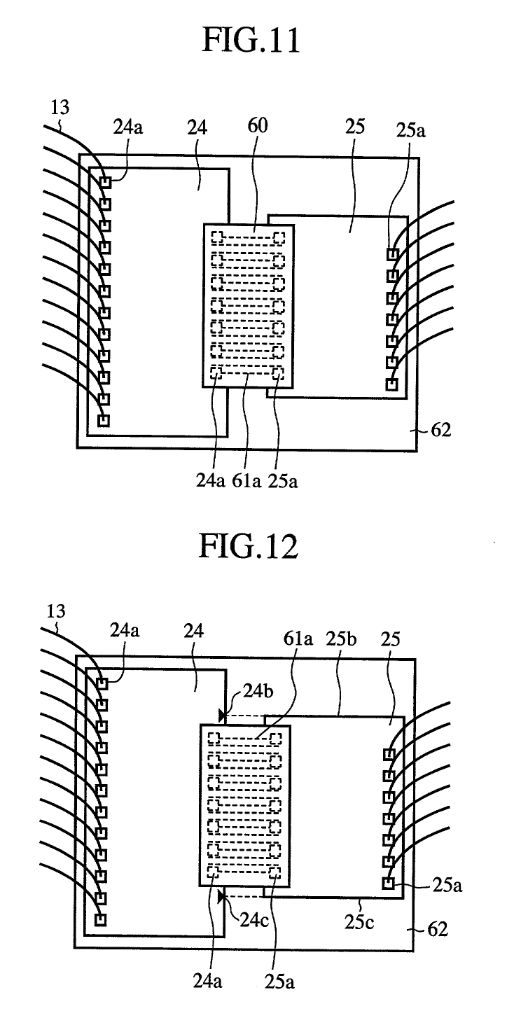

FIG. 11 is a plan view of a semiconductor device in which the connection seal 60 shown in FIG. 10 is used. As shown in FIG. 11, the chips 24 and 25 are arranged on a die pad 62 at a prescribed interval. The die pad 62 is used to fix a chip such as a substrate. A plurality of pads 24a are arranged on both right and left side ends of the chip 24. The pads 24a arranged on the left side of the chip 24 are spaced at a specified pitch and are arranged in an arrangement direction at an arrangement length, and the pads 24a arranged on the right side of the chip 24 are spaced at the specified pitch and are arranged in the arrangement direction at another arrangement length. Also, a plurality of pads 25a are arranged on both right and left side ends of the chip 25. The pads 25a arranged on the left side of the chip 25 are spaced at the specified pitch and are arranged in the arrangement direction at the same arrangement length as that of the pads 24a arranged on the right side of the chip 24, and the pads 25a arranged on the right side of the chip 25 are spaced at the specified pitch and are arranged in the arrangement direction at another arrangement length.

The connection seal 60 is attached to the die pad 62 so as to connect the chips 24 and 25. In detail, the main surface of the connection seal 60 is directed downward, and the connection seal 60 is put on the die pad 62 so as to attach the main surface of the connection seal 60 to the right side end of the chip 24 and the left side end of the chip 25. Therefore, the pads 24a placed on the right side of the chip 24 are connected to the pads 25a placed on the left side of the chip 25 through the patterned lead wires 61a of the lead wire pattern unit 61 arranged on the main surface of the connection seal 60. In this embodiment, the arrangement length of the patterned lead wires 61a of the connection seal 60 is set to be equal to those of the pads 24a and 25a of the chips 24 and 25. Also, the pads 25a placed on the left side of the chip 25 are arranged so as to be connected to the corresponding pads 24a placed on the right side of the chip 24 respectively in signal transmission.

A width of the patterned lead wires 61a is smaller than a width of an open space formed between each pair of pads 24a or 25a adjacent to each other. Also, a width of the pads 24a and 25a is larger than a width of an open space formed between each pair of patterned lead wires 61a adjacent to each other. Therefore, the pitch of the patterned lead wires 61a is smaller than the pitch of the pads 24a and 25a of the chips 24 and 25.

In this case, because the width of each pad 24a or 25a of the chips 24 and 25 is larger than the width of an open space formed between each pair of patterned lead wires 61a of the connection seal 60 adjacent to each other, each pad 24a or 25a of the chips 24 and 25 necessarily makes contact with one patterned lead wire 61a of the connection seal 60. Also, because the width of each patterned lead wire 61a of the connection seal 60 is smaller than the width of an open space formed between each pair of pads 24a or 25a adjacent to each other, each pad 24a or 25a of the chips 24 and 25 is not electrically connected to the other pads 24a or 25a.

Each patterned lead wire 61a making contact with the pad 24a or 25a is called a contact lead wire in this specification. Each pad 24a of the chip 24 is connected to the pad 25a of the chip 25 corresponding to the pad 24a in signal transmission through one contact lead wire 61a. Also, the pads 24a placed on the left side of the chip 24 and the pads 25a placed on the right side of the chip 25 are connected to a plurality of wires 13 respectively according to the wire bonding. Therefore, a signal sent from an external device is received in the chip 24 of semiconductor device through one bonding wire 13 and the pad 24a making contact with the bonding wire 13, a signal of the chip 24 of the semiconductor device is sent to the chip 25 of the semiconductor device through another pad 24a, the contact lead wire 61a making contact with the pad 24a and the pad 25a connected to the contact lead wire 61a, and a signal of the chip 25 of the semiconductor device is sent out to another external device through another pad 25a and the bonding wire 13 connected to the pad 25a.

In the fifth embodiment, the two chips 24 and 25 are connected to each other through the connection seal 60 to obtain the semiconductor device. However, it is applicable that three chips or more be connected to each other by using a plurality of connection seals 60. In this case, one connection seal 60 is placed so as to connect each pair of chips placed at a prescribed interval.

As is described above, in the fifth embodiment, the arrangement length of the patterned lead wires 61a of the connection seal 60 is set to be equal to that of pads of a specific chip having a maximum size and a maximum arrangement length among a plurality of chips prepared to be used in a semiconductor device, the width of the patterned lead wires 61a of the connection seal 60 is smaller than the width of an open space between each pair of adjacent pads of each chip, and the width of the pads of the chips is larger than the width of an open space between each pair of adjacent patterned lead wires 61a of the connection seal 60. Therefore, in cases where the connection seal 60 having the patterned lead wires 61a is used to connect a plurality of chips of the semiconductor device, even though any chips having sizes smaller than the maximum-sized chip are used for the semiconductor device or even though chips of the maximum size respectively having pads, of which the number is smaller than that of the maximum-sized chip, are used for the semiconductor device, each pad of the chips can reliably make contact with one patterned lead wire 61a of the connection seal 60 without electrically connecting each pad of the chips to the other pads. Accordingly, any chip can be used for the semiconductor device regardless of the specification of the size of the chip, and the increase of the cost in the manufacturing of the semiconductor device due to the specification of the size determined for each chip can be suppressed.

Also, in the fifth embodiment, even though a plurality of chips prepared to be used for a semiconductor device have pad pitches different from each other, because the pads of each chip are arranged on condition that the width of an open space between each pair of adjacent pads of the chip is larger than the width of the patterned lead wires 61a of the connection seal 60, any chip can be used for a semiconductor device so as to make each pad of the chip be electrically connected to one patterned lead wire 61a without electrically connecting each pad of the chip to the other pads. Accordingly, any chips can be used for a semiconductor device regardless of the specification of the pad pitch of the chip, and the increase of the cost in the manufacturing of the semiconductor device due to the specification of the pad pitch determined for each chip can be suppressed.

Also, in the fifth embodiment, each pad 24a of the chip 24 is reliably connected to the corresponding pad 25a of the chip 25 through one patterned lead wire 61a of the connection seal 60 by only arranging the connection seal 60 between the chips 24 and 25, a plurality of chips arranged on the die pad 62 can be easily connected to each other by using one connection seal 60 or more.

EMBODIMENT 6

FIG. 12 is a plan view showing a semiconductor device according to a sixth embodiment of the present invention. In this embodiment, the chips 24 and 25 are connected to each other by using the connection seal 60 described in the fifth embodiment. In detail, a pair of positioning marks 24b and 24c are attached to a first chip (in this embodiment, the chip 24) of which a side facing a second chip (in this embodiment, the chip 25) is longer than a side of the second chip facing the side of the first chip. When the chips 24 and 25 are arranged on the die pad 62, the chips 24 and 25 are accurately positioned on the die pad 62 according to the positioning marks 24b and 24c of the chip 24.

The positioning marks 24b and 24c are spaced at a fixed distance apart on the chip 24, and the fixed distance is equal to a distance between an upper side 25b and a lower side 25c of the chip 25 perpendicular to the side of the chip 24 facing the chip 25. Also, the positioning marks 24b and 24c are attached to the chip 24 while considering the connection relationship between the pads 24a of the chip 24 and the pads 25a of the chip 25 in signal transmission.

The chips 24 and 25 are positioned on the die pad 62 so as to place the positioning marks 24b and 24c on extension lines of the upper and lower sides 25b and 25c of the chip 25 respectively. After the chips 24 and 25 are positioned on the die pad 62, the connection seal 60 is arranged on the die pad 62 so as to connect the chips 24 and 25 to each other.

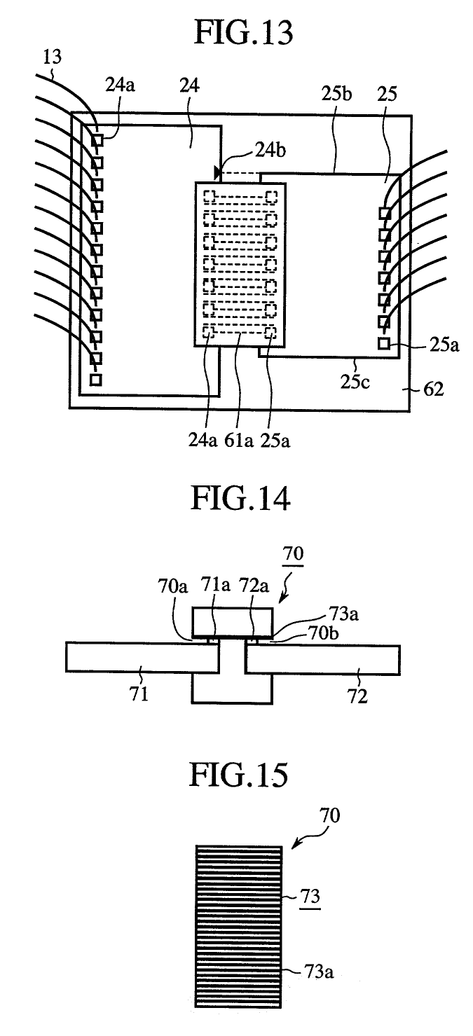

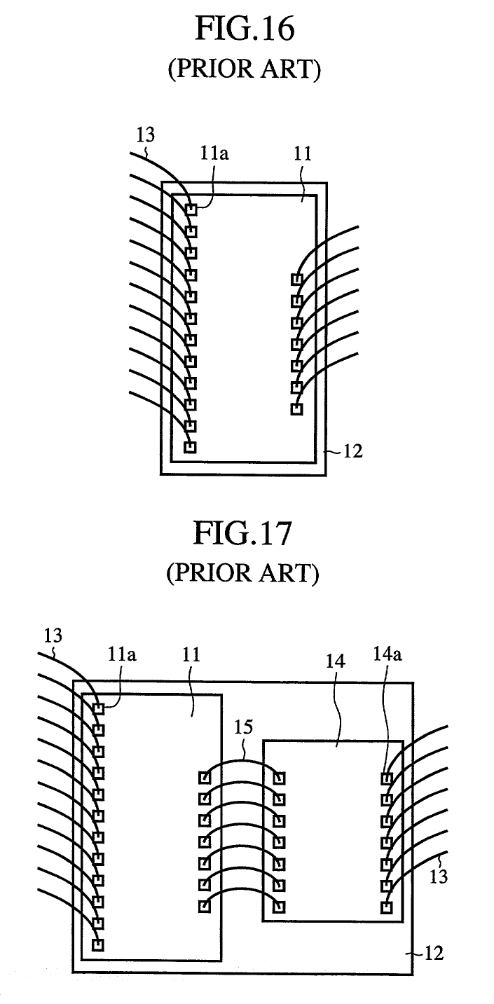

In this embodiment, two positioning marks 24b and 24c are attached to the chip 24. However, it is applicable that only one positioning mark be attached to a first chip having a longer side to position both the first chip and a second chip by placing the positioning mark of the first chip on an extension line of an upper or lower side of the second chip. For example, as shown in FIG. 13, only the positioning mark 24b is attached to the chip 24, and the chip 25 is positioned on the die pad 62 so as to place the positioning mark 24b on an extension line of the upper side 25b of the chip 25. Also, when three chips or more are arranged on the die pad 62, it is applicable that only one positioning mark be attached to a chip having a longer side between each pair of chips facing each other. Therefore, a marking operation can be reduced in the manufacturing of the semiconductor device.

As is described above, in the sixth embodiment, because a plurality of chips are arranged on the die pad 62 while positioning the chips according to one positioning mark or more, in addition to the effect obtained in the fifth embodiment, each pad of a first chip corresponding to a pad of a second chip in signal transmission can be reliably connected to the corresponding pad of the second chip by using the connection seal 60, and the yield of the semiconductor device can be improved.

EMBODIMENT 7

FIG. 14 is a cross sectional view showing a semiconductor device according to a seventh embodiment of the present invention. In FIG. 14, 70 indicates a socket (or an electric connection member). 71 and 72 indicate a pair of chips. A plurality of pads 71a are arranged in equal intervals on both side ends (a right side end and a left side end in FIG. 14) of the chip 71, and a plurality of pads 72a are arranged in equal intervals on both side ends (a right side end and a left side end in FIG. 14) of the chip 72. An insert hole 70a and an insert hole 70b are arranged on both side ends (a right side end and a left side end in FIG. 14) of the socket 70.

FIG. 15 is a plan view showing an inner plane of the socket 70 used for the semiconductor device shown in FIG. 14. As shown in FIG. 15, a lead wire pattern unit (or an electric connection pattern unit) 73 is arranged on an inner plane of the socket 70, and a plurality of patterned lead wires 73a respectively extending from the insert hole 70a to the insert hole 70b are arranged in the lead wire pattern unit 73 in equal intervals at an arrangement length. The arrangement length of the patterned lead wires 73a is set to be equal to that of pads of a specific chip having a maximum size and a maximum arrangement length among a plurality of chips prepared to be used for the semiconductor device. A width of the pads 71a of the chip 71 in an arrangement direction of the pads 71a and a width of the pads 72a of the chip 72 in an arrangement direction of the pads 72a are longer than an open space formed between each pair of patterned lead wires 73a of the socket 70 adjacent to each other, and a width of each patterned lead wire 73a of the socket 70 is smaller than both an open space formed between each pair of pads 71a of the chip 71 adjacent to each other and an open space formed between each pair of pads 72a of the chip 72 adjacent to each other.

One end portion (a right end portion in FIG. 14) of the chip 71, in which the pads 71a are arranged, is inserted into the insert hole 70a of the socket 70, and one end portion (a left end portion in FIG. 14) of the chip 72, in which the pads 72a are arranged, is inserted into the insert hole 70b of the socket 70. Therefore, each pad 71a of the chip 71 reliably makes contact with one patterned lead wire 73a of the socket 70 without making contact with the other pads 71a, each pad 72a of the chip 72 reliably makes contact with one patterned lead wire 73a of the socket 70 without making contact with the other pads 72a, and the pads 71a of the chip 71 and the pads 72a of the chip 72 are connected to each other through the patterned lead wires 73a of the socket 70 in one-to-one correspondence.

Each patterned lead wire 73a making contact with the pads 71a and 72a of the chips 71 and 72 is called a contact lead wire in this specification. The pads 71a and the pads 72a are arranged on the chips 71 and 72 so as to connect each pad 71a with one pad 72a corresponding to the pad 71a in signal transmission through one contact lead wire 73a.

In the seventh embodiment, the two chips 71 and 72 are connected to each other through the socket 70 to obtain the semiconductor device. However, it is applicable that three chips or more be serially connected to each other by using a plurality of sockets 70. In this case, each pair of chips adjacent to each other are connected to each other through one socket 70.

As is described above, in the seventh embodiment, the arrangement length of the patterned lead wires 73a of the socket 70 is set to be equal to that of pads of a specific chip having a maximum size and a maximum arrangement length among a plurality of chips prepared to be used for the semiconductor device, the width of the pads of each chip is longer than an open space between each pair of patterned lead wires 73a of the socket 70 adjacent to each other, the width of each patterned lead wire 73a of the socket 70 is smaller than an open space formed between each pair of adjacent pads of the chips, and each pair of first and second chips adjacent to each other are inserted into the insert holes 70a and 70b of the socket 70 so as to connect the pads of the first chip with the pads of the second chip through the contact lead wires 73a. Therefore, even though any chips having sizes smaller than the maximum-sized chip are inserted into the insert holes 70a and 70b of the socket 70 or even though chips of the maximum size respectively having pads, of which the number is smaller than that of the maximum-sized chip, are inserted into the insert holes 70a and 70b of the socket 70, each pad of the first chip can reliably make contact with one patterned lead wire 73a of the socket 70 without making contact with the other pads, each pad of the second chip can reliably make contact with one patterned lead wire 73a of the socket 70 without making contact with the other pads, and the pads of the first chip and the pads of the second chip can be connected to each other through the patterned lead wires 73a of the socket 70 in one-to-one correspondence. Accordingly, any chips can be used for the semiconductor device having the socket 70 regardless of the specification of the sizes of the chips, and the increase of the cost in the manufacturing of the semiconductor device due to the specification of the size determined for each chip can be suppressed.

Also, in the seventh embodiment, even though the chips prepared to be used for the semiconductor device have pad pitches different from each other, because the pads of each chip are arranged on condition that the width of an open space between each pair of adjacent pads of the chip is larger than the width of the patterned lead wires 73a of the socket 70, each pad of a first chip can reliably make contact with one patterned lead wire 73a of the socket 70 without making contact with the other pads, each pad of a second chip can reliably make contact with one patterned lead wire 73a of the socket 70 without making contact with the other pads, and the pads of the first chip and the pads of the second chip can be connected to each other through the patterned lead wires 73a of the socket 70 in one-to-one correspondence. Accordingly, any chips can be used for the semiconductor device having the socket 70 regardless of the specifications of the pad pitches of the chips, and the increase of the cost in the manufacturing of the semiconductor device due to the specification of the pad pitch determined for each chip can be suppressed.

Also, in the seventh embodiment, because the pads of a pair of chips adjacent to each other can be connected to each other through the patterned lead wires 73a of the socket 70 in one-to-one correspondence by inserting the chips into the insert holes 70a and 70b of the socket 70, a plurality of chips can be easily connected to each other in series.

What is claimed is:

1. A semiconductor device comprising:
a semiconductor chip on which a plurality of electric connection terminals are arranged to be equally spaced at a pitch;
a supporting member having a chip mounting surface on which the semiconductor chip is mounted; and
an electric connection pattern unit, which is arranged on the chip mounting surface of the supporting member and has a plurality of patterned lead wires equally spaced at another pitch and making contact with the electric connection terminals of the semiconductor chip on condition that an arrangement length of the group of patterned lead wires is equal to or longer than that of the group of electric connection terminals of the semiconductor chip, widths of the patterned lead wires are smaller than a width of an open space between each pair of electric connection terminals adjacent to each other in the semiconductor chip, and widths of the electric connection terminals of the semiconductor chip are larger than a width of an open space between each pair of patterned lead wires adjacent to each other.

2. A semiconductor device according to claim 1, wherein the widths of the electric connection terminals of the semiconductor chip are larger than the width of the open space between side end portions of each pair of patterned lead wires adjacent to each other, only the side end portions of the patterned lead wires make contact with the electric connection terminals of the semiconductor chip, and an arrangement length of the group of side end portions of the patterned lead wires is equal to that of the group of electric connection terminals of the semiconductor chip.

3. A semiconductor device according to claim 2, wherein the other side end portions of the patterned lead wires of the electric connection pattern unit are equally spaced at a bonding pitch of a plurality of bonding wires, and the bonding wires are connected to the other side end portions of the patterned lead wires respectively to electrically connect each patterned lead wire to an external device through the corresponding bonding wire.

4. A semiconductor device comprising:
a plurality of semiconductor chips respectively having a plurality of electric connection terminals equally spaced at a pitch;
a supporting member having a chip mounting surface on which the semiconductor chips are mounted; and
an electric connection pattern unit which corresponds to each pair of semiconductor chips adjacent to each other among the semiconductor chips, is arranged on the chip mounting surface of the supporting member and has a plurality of patterned lead wires equally spaced at another pitch and making contact with two groups of electric connection terminals of the pair of semiconductor chips to electrically connect the pair of semiconductor chips on condition that an arrangement length of the group of patterned lead wires is equal to or longer than those of the groups of electric connection terminals of the pair of semiconductor chips, widths of the patterned lead wires are smaller than a width of an open space between each pair of electric connection terminals adjacent to each other in each of the pair of semiconductor chips, and widths of the electric connection terminals of the pair of semiconductor chips are larger than a width of an open space between each pair of patterned lead wires adjacent to each other.

5. A semiconductor device according to claim 4, wherein the electric connection pattern unit has an external connection pattern unit which is arranged on the chip mounting surface of the supporting member and has a plurality of external patterned lead wires equally spaced and making contact with the electric connection terminals of one semiconductor chip to electrically connect the semiconductor chip and an external device on condition that an arrangement length of the group of external patterned lead wires is equal to or longer than that of the group of electric connection terminals of the semiconductor chip, widths of the external patterned lead wires are smaller than a width of an open space between each pair of electric connection terminals adjacent to each other in the semiconductor chip, and widths of the electric connection terminals of the semiconductor chip are larger than a width of an open space between each pair of external patterned lead wires adjacent to each other.

6. A semiconductor device according to claim 5, wherein the widths of the electric connection terminals of the semiconductor chip are larger than the width of the open space between side end portions of each pair of external patterned lead wires adjacent to each other in the external connection pattern unit, only the side end portions of the pair of external patterned lead wires make contact with the electric connection terminals of the semiconductor chip, and an arrangement length of the group of side end portions of the pair of external patterned lead wires is equal to that of the group of electric connection terminals of the semiconductor chip.

7. A semiconductor device according to claim 6, wherein the other side end portions of the external patterned lead wires of the external electric connection pattern unit are equally spaced at a bonding pitch of a plurality of bonding wires, and the bonding wires are connected to the other side end portions of the external patterned lead wires respectively to electrically connect each external patterned lead wire to an external device through the corresponding bonding wire.

8. A semiconductor device comprising:
a plurality of semiconductor chips respectively having a plurality of electric connection terminals equally spaced at a pitch; and
an electric connection member which corresponds to each pair of semiconductor chips adjacent to each other among the semiconductor chips, has a plurality of patterned lead wires equally spaced at another pitch and is arranged between the pair of semiconductor chips so as to make contact with two groups of electric connection terminals of the pair of semiconductor chips and to electrically connect the pair of semiconductor chips on condition that an arrangement length of the group of patterned lead wires is equal to or longer than those of the groups of electric connection terminals of the pair of semiconductor chips, widths of the patterned lead wires are smaller than a width of an open space between each pair of electric connection terminals adjacent to each other in each of the pair of semiconductor chips, and widths of the electric connection terminals of the pair of semiconductor chips are larger than a width of an open space between each pair of patterned lead wires adjacent to each other.

9. A semiconductor device according to claim 8, wherein a positioning mark is attached to one of the pair of semiconductor chips.

10. A semiconductor device according to claim 8, wherein the electric connection member is formed in a socket shape and has a pair of insert holes, the patterned lead wires of the electric connection member extend from one insert hole to the other insert hole, and the electric connection terminals of the pair of semiconductor chips are connected to each other through the patterned lead wires of the electric connection member by inserting the pair of semiconductor chips into the insert holes of the electric connection member.
